(19) United States
(12) Patent Application Publication
(10) Pub. No.: US 2025/0218802 A1
(43) Pub. Date: Jul. 3, 2025

(54) SUBSTRATE TREATMENT SYSTEM AND SUBSTRATE TREATMENT METHOD

(71) Applicant: Tokyo Electron Limited, Tokyo (JP)

(72) Inventor: Keiichi YAHATA, Koshi City, Kumamoto (JP)

(21) Appl. No.: 18/707,235

(22) PCT Filed: Nov. 17, 2021
(86) PCT No.: PCT/JP2021/042176

§ 371 Date: May 3, 2024

(51) Int. Cl. H01L 21/67; H01L 21/027

(52) U.S. Cl. CPC H01L 21/67017; H01L 21/0274; H01L 21/67109

(57) ABSTRACT

A substrate treatment system connected to an exposure apparatus, includes: a substrate treatment apparatus configured to perform a treatment on a substrate; and a first supply path connecting the substrate treatment apparatus and the exposure apparatus and configured to supply cooling water used in the substrate treatment apparatus to the exposure apparatus.

### TECHNICAL FIELD

This disclosure relates to a substrate treatment system and a substrate treatment method.

### BACKGROUND ART

Patent Document 1 discloses a developing apparatus including a developing bath for performing a developing treatment, a developing solution storage tank storing a developing solution to be supplied to the developing bath, and a circulation cooling system for circulating cooling water to cool the developing solution in the developing solution storage tank.

### PRIOR ART DOCUMENT

### Patent Document

Patent Document 1: Japanese Laid-open Patent Publication No. 2011-192775

### DISCLOSURE OF THE INVENTION

### Problems to Be Solved by the Invention

The technique according to this disclosure reduces the total cooling water usage in a substrate treatment system and an exposure apparatus.

### Means for Solving the Problems

An aspect of this disclosure is a substrate treatment system connected to an exposure apparatus, the substrate treatment system including: a substrate treatment apparatus configured to perform a treatment on a substrate; and a first supply path connecting the substrate treatment apparatus and the exposure apparatus and configured to supply cooling water used in the substrate treatment apparatus to the exposure apparatus.

### Effect of the Invention

According to this disclosure, it is possible to reduce the total cooling water usage in a substrate treatment system and an exposure apparatus.

### BRIEF DESCRIPTION OF THE DRAWINGS

FIG. 1 is a view schematically illustrating a configuration of a substrate treatment system according to a first embodiment.

FIG. 2 is an explanatory view illustrating the outline of an internal configuration of a coating and developing treatment apparatus as a substrate treatment apparatus included in the substrate treatment system in FIG. 1.

FIG. 3 is a view illustrating an example of a supply form of atmosphere gas to the coating and developing treatment apparatus.

FIG. 4 is a view schematically illustrating a configuration of a substrate treatment system according to a second embodiment.

FIG. 5 is a view schematically illustrating a configuration of a substrate treatment system according to a third embodiment.

FIG. 6 is a view schematically illustrating a configuration of a substrate treatment system according to a fourth embodiment.

FIG. 7 is a view schematically illustrating a configuration of a substrate treatment system according to a modification example of the fourth embodiment.

### EMBODIMENTS FOR CARRYING OUT THE INVENTION

In a manufacturing process of a semiconductor device or the like, predetermined treatments are performed in order to form a resist pattern on a substrate such as a semiconductor wafer (hereinafter, referred to as a “wafer”). The predetermined treatments are, for example, a resist coating treatment of supplying a resist solution onto the substrate to form a coating film of a resist, an exposure treatment of exposing the coating film, a heat treatment of heating the substrate before/after the exposure treatment, a developing treatment of developing the exposed coating film, and so on.

The above resist coating treatment, heat treatment, and developing treatment are performed in a resist coating unit, a thermal treatment unit, and a developing treatment unit, respectively. Those units which perform necessary treatments other than the exposure treatment are installed in a coating and developing treatment apparatus being a substrate treatment apparatus. The coating and developing treatment apparatus is used in connection with an exposure apparatus which performs the exposure treatment.

Incidentally, a large amount of cooling water is used in the coating and developing treatment apparatus. The cooling water is used, for example, for cooling a developing solution to be used for the developing treatment and for the substrate after the thermal treatment.

Further, cooling water is used also in the exposure apparatus.

Therefore, the total cooling water usage by the coating and developing treatment apparatus and the exposure apparatus is extremely large.

Hence, the technique according to this disclosure reduces the total cooling water usage in a substrate treatment system including a substrate treatment apparatus such as a coating and developing treatment apparatus and in an exposure apparatus.

Hereinafter, a substrate treatment system and a substrate treatment method according to embodiments will be explained with reference to the drawings. Note that, in the description and the drawings, components having substantially the same functional configurations are denoted by the same reference signs to omit duplicate explanations.

### First Embodiment

### Substrate Treatment System

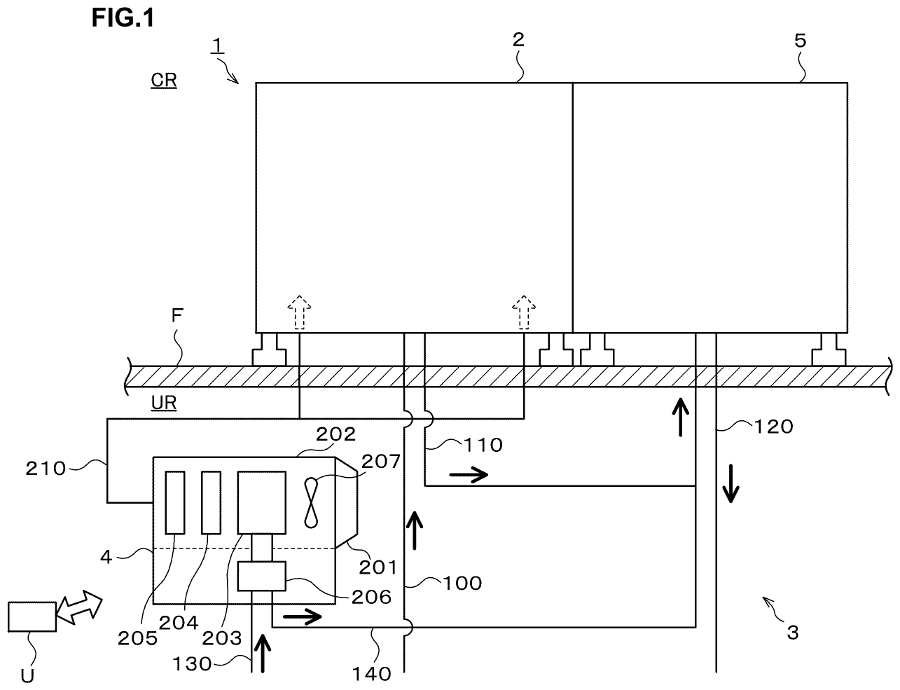

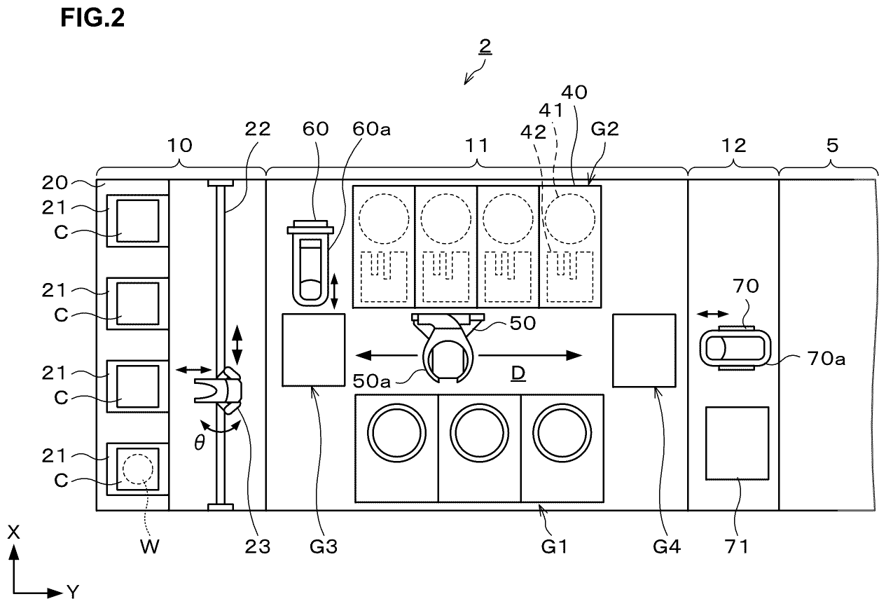

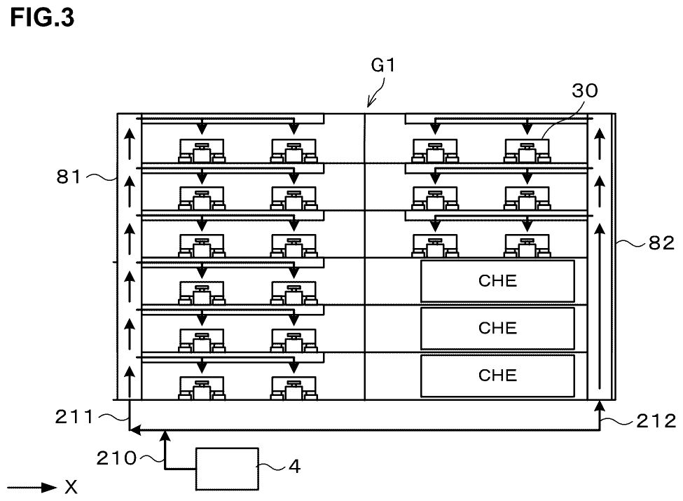

FIG. 1 is a view schematically illustrating a configuration of a substrate treatment system according to a first embodiment, and FIG. 2 is an explanatory view illustrating the outline of an internal configuration of a coating and developing treatment apparatus as a substrate treatment apparatus included in the substrate treatment system in FIG. 1. FIG. 3 is a view illustrating an example of a supply form of atmosphere gas to the coating and developing treatment apparatus.

The substrate treatment system 1 includes a coating and developing treatment apparatus 2, a cooling water supply apparatus 3, and a gas supply apparatus 4 as illustrated in FIG. 1. To the coating and developing treatment apparatus 2, an exposure apparatus 5 is connected.

The coating and developing treatment apparatus 2 is intended to perform treatments on a wafer W as a substrate, and has a cassette station 10 into/out of which a cassette C housing a plurality of wafers W is transferred, and a treatment station 11 including a plurality of various treatment units which perform the predetermined treatments on the wafer Was illustrated in FIG. 2. The coating and developing treatment apparatus 2 has a configuration in which the cassette station 10, the treatment station 11, and an interface station 12 which delivers the wafer W to/from the exposure apparatus 5 adjacent to the treatment station 11 are integrally connected.

In the cassette station 10, a cassette stage 20 is provided. On the cassette stage 20, a plurality of cassette stage plates 21 on which the cassettes C are mounted when the cassettes C are transferred in/out from/to the outside of the coating and developing treatment apparatus 2.

In the cassette station 10, a wafer transfer unit 23 is provided which is movable on a transfer path 22 extending in an X-direction. The wafer transfer unit 23 is movable also in an up-down direction and around a vertical axis (in a θ-direction), and can transfer the wafer W between the cassette C on each of the cassette stage plates 21 and a delivery unit (not illustrated) in a third block G3 of the treatment station 11.

In the treatment station 11, a plurality of, for example, four blocks G1, G2, G3, G4 each including various units are provided. For example, the first block G1 is provided on the front side (an X-direction negative direction side in FIG. 2) in the treatment station 11, and the second block G2 is provided on the rear side (an X-direction positive direction side in FIG. 2) in the treatment station 11. Further, the third block G3 is provided on the cassette station 10 side (a Y-direction negative direction side in FIG. 2) in the treatment station 11, and the fourth block G4 is provided on the interface station 12 side (a Y-direction positive direction side in FIG. 2) in the treatment station 11.

In the first block G1, solution treatment units 30 such as a resist coating unit and a developing treatment unit are provided. A plurality of the solution treatment units 30 are arranged to line up in the horizontal direction and the up-down direction as illustrated in FIG. 3. The solution treatment unit 30 supplies a predetermined treatment solution onto the wafer W, for example, by a spin coating method. In the spin coating method, the treatment solution is discharged onto the wafer W, for example, from a discharge nozzle and the wafer W is rotated, whereby the treatment solution is diffused over a surface of the wafer W.

As illustrated in FIG. 2, in the second block G2, a thermal treatment unit 40 is provided which performs thermal treatments such as heating and cooling of the wafer W. A plurality of the thermal treatment units 40 are arranged to line up in the horizontal direction and the up-down direction as with the solution treatment units 30.

The thermal treatment unit 40 has a hot plate 41 and a cooling plate 42. The wafer W is mounted on the hot plate 41, and the hot plate 41 heats the mounted wafer W. The wafer W is mounted on the cooling plate 42, and the cooling plate 42 cools the mounted wafer W. In one embodiment, inside the cooling plate 42, a cooling water flow path is provided.

For example, in each of the third block G3 and the fourth block G4, delivery units (not illustrated) are provided at multiple stages.

In a region surrounded by the first block G1 to the fourth block G4, a wafer transfer region D is formed. In the wafer transfer region D, a wafer transfer unit 50 is arranged.

The wafer transfer unit 50 has a transfer arm 50a movable, for example, in a Y-direction, the X-direction, the θ-direction, and the up-down direction. The wafer transfer unit 50 can move in the wafer transfer region D to transfer the wafer W to a predetermined unit in the first block G1, the second block G2, the third block G3, and the fourth block G4 therearound.

Further, adjacent to the X-direction positive direction side of the third block G3, a wafer transfer unit 60 is provided. The wafer transfer unit 60 has a transfer arm 60a movable, for example, in the X-direction, the θ-direction, and the up-down direction. The wafer transfer unit 60 can move up and down in a state of supporting the wafer W to transfer the wafer W to each of the delivery units (not illustrated) in the third block G3.

In the interface station 12, a wafer transfer unit 70 and a delivery unit 71 are provided. The wafer transfer unit 70 has a transfer arm 70a movable, for example, in the Y-direction, the θ-direction, and the up-down direction. The wafer transfer unit 70 can transfer the wafer W between the delivery unit 71 in the fourth block G4 and the exposure apparatus 5, for example, while supporting the wafer W by the transfer arm 70a.

As illustrated in FIG. 1, the cooling water supply apparatus 3 has supply paths 100, 110 and a return path 120.

The supply path 100 supplies the cooling water to be used in the coating and developing treatment apparatus 2 to the coating and developing treatment apparatus 2. In the coating and developing treatment apparatus 2, the cooling water is used, for example, for cooling the wafer W using the cooling plate 42 and for cooling the treatment solution such as a developing solution. The cooling water to be supplied to the coating and developing treatment apparatus 2 is required to be set at, for example, 25° C. or lower, and the temperature of the cooling water to be actually supplied to the coating and developing treatment apparatus 2 is, for example, 15° C. to 25° C. Further, the temperature of the cooling water after it is used in the coating and developing treatment apparatus 2 is, for example, 25° C. to 35° C. though depending on the purpose and form of use of the cooling water.

The supply path 110 connects the coating and developing treatment apparatus 2 and the exposure apparatus 5 and supplies the cooling water used in the coating and developing treatment apparatus 2 to the exposure apparatus 5. In the exposure apparatus 5, the cooling water is used for cooling the light source for an exposure treatment and the like. The cooling water to be used in the exposure apparatus 5 is often permitted to be higher in temperature than the cooling water to be used in the coating and developing treatment apparatus 2, and the required temperature is, for example, 35° C. or lower.

The return path 120 returns the cooling water used in the exposure apparatus 5 to a chiller unit (not illustrated). The cooling water returned to the chiller unit is supplied again to the coating and developing treatment apparatus 2 via the supply path 100.

Supply paths 130, 140 of the cooling water supply apparatus 3 will be explained later.

The gas supply apparatus 4 supplies the atmosphere gas during a substrate treatment to the coating and developing treatment apparatus 2. The coating and developing treatment apparatus 2 and the exposure apparatus 5 are installed on an upper surface of a floor F in a clean room CR, whereas the gas supply apparatus 4 is installed in an underfloor space UR being a lower space of the floor F. The floor F is composed of a gas-permeable flooring material usually called grating. Accordingly, the atmosphere in the underfloor space UR is an atmosphere originating from the clean room CR. Thus, the atmosphere in an installation area in this disclosure includes not only the atmosphere in the clean room CR in which the coating and developing treatment apparatus 2, the exposure apparatus 5, and so on are installed but also the atmosphere in the underfloor space UR of the floor F on which the coating and developing treatment apparatus 2, the exposure apparatus 5, and so on are installed.

The gas supply apparatus 4 has an intake part 201 which takes in the atmosphere in the underfloor space UR, and regulates the temperature and humidity of the atmosphere in the underfloor space UR taken in from the intake part 201 and supplies it as atmosphere gas to the coating and developing treatment apparatus 2. The gas supply apparatus 4 has a cooling part 203, a heating part 204, and a humidifying part 205 in order from the upstream, for example, in a flow path in a casing 202. The cooling part 203 is composed of, for example, a cooling coil. The cooling part 203 has, for example, a function of cooling the gas taken in from the intake part 201 to a dew-point temperature or lower with cooling water or a refrigerant supplied from a cooling unit 206 to dehumidify the gas.

The cooling unit 206 includes various instruments which realize a refrigeration cycle, composed of, for example, a compressor, an expansion valve, and so on. The cooling unit 206 may be, for example, a heat pump composition. The illustrated cooling unit 206 further has a configuration of cooling the refrigerant increased in temperature in the refrigeration cycle, with cooling water (for example, 15° C. to 25° C.) supplied from the outside. Accordingly, the cooling water used in the cooling unit 206 and discharged from the cooling unit 206 has been increased in temperature (for example, 25° C. to 40° C.).

Examples of the heating part 204 include a heater functioning as a so-called reheater which generates heat by the supply of electric power and a heating coil which generates heat by the supply of hot water.

As the humidifying part 205, for example, a humidifier having a configuration which sprays water or supplies water vapor can be employed.

Through use of the above cooling part 203, heating part 204, and humidifying part 205, the gas taken in from the intake part 21 is first dehumidified by the cooling part 203, then heated by the heating part 204 up to a desired temperature, and then humidified by the humidifying part 205 up to a desired humidity. The gas thus regulated to the desired temperature and humidity is supplied as the atmosphere gas by a fan 207 to the coating and developing treatment apparatus 2, for example, via a duct 210. Note that the duct 210 only needs to be a closed flow path through which gas flows without leakage regardless of its name, and may be, for example, a pipe or a tube.

The atmosphere gas regulated in temperature and humidity by the gas supply apparatus 4 is supplied, for example, to a ceiling part at each stage by main ducts 81, 82 provided in the coating and developing treatment apparatus 2 via ducts 211, 212 branched from the duct 210, as illustrated in FIG. 3. The atmosphere gas supplied to the ceiling part at each stage is supplied to each of the solution treatment units 30. The temperature and humidity of the atmosphere gas are generally, for example, 23° C., 45% RH, but preferable temperature and humidity are not limited to them depending on the type and the details of the treatment of the solution treatment unit 30 at its supply destination.

The above cooling water supply apparatus 3 further has the supply paths 130, 140 as illustrated in FIG. 1.

The supply path 130 supplies the cooling water to be used in the gas supply apparatus 4 to the gas supply apparatus 4. The supply path 130 concretely supplies the cooling water to be used in the cooling unit 206 in the gas supply apparatus 4 to the cooling unit 206. The temperature of the cooling water to be supplied to the cooling unit 206 is, for example, 15° C. to 25° C. as explained above. Further, the temperature of the cooling water after it is used in the cooling unit 206 is, for example, 25° C. to 40° C.

The supply path 140 connects the gas supply apparatus 4 and the exposure apparatus 5 and supplies the cooling water used in the gas supply apparatus 4 to the exposure apparatus 5.

In this embodiment, the supply path 110 and the supply path 140 merge on the exposure apparatus 5 side. Accordingly, the cooling water supply apparatus 3 mixes the cooling water used in the coating and developing treatment apparatus 2 and the cooling water used in the gas supply apparatus 4 and then supplies them to the exposure apparatus 5. Further, the cooling water used in the exposure apparatus 5 is returned to the chiller unit (not illustrated) via the return path 120, cooled down to a predetermined temperature, distributed into the supply path 100 and the supply path 130, and supplied again to the coating and developing treatment apparatus 2 and the gas supply apparatus 4. In other words, in this embodiment, the supply paths 100, 110 and the return path 120 constitute a first circulation path being a circulation path of the cooling water for the coating and developing treatment apparatus 2 and the exposure apparatus 5, and the supply paths 130, 140 and the return path 120 constitute a second circulation path of the cooling water for the gas supply apparatus 4 and the exposure apparatus 5. Further, the first circulation path and the second circulation path share the piping such as the return path 120, the chiller unit, and so on.

Note that though not illustrated, the cooling water supply apparatus 3 has pressure-feeding means such as a pump for pressure-feeding the cooling water cooled in the chiller unit to the coating and developing treatment apparatus 2 and the gas supply apparatus 4.

Further, in the substrate treatment system 1, a control device U is provided. The control device U is a computer including, for example, a processor such as a CPU, a memory and so on, and has a program storage (not illustrated). The program storage stores a program for the temperature and humidity regulation in the gas supply apparatus 4. As a matter of course, the control device U may be shared with a control device which controls various treatment units and transfer units which are installed in the substrate treatment system 1 and a control device which performs control of various treatments of the exposure apparatus 5. The above program may be the one which is recorded in a computer-readable storage medium and installed from the storage medium into the control device. The storage medium may be a transitory one or a non-transitory one. Further, the above program may be the one which is installed over the Internet. Furthermore, part of all of the program may be realized by dedicated hardware (circuit board).

### Main Operations and Effects

As explained above, in this embodiment, the substrate treatment system 1 connected to the exposure apparatus 5 has the supply path 110 which connects the coating and developing treatment apparatus 2 and the exposure apparatus 5 and supplies the cooling water used in the coating and developing treatment apparatus 2 to the exposure apparatus 5. In other words, in this embodiment, by providing the supply path 110 without separately providing a supply path of the cooling water for the coating and developing treatment apparatus 2 and a supply path of the cooling water for the exposure apparatus 5, the cooling water used in the coating and developing treatment apparatus 2 is used also in the exposure apparatus 5. Therefore, according to this embodiment, it is possible to reduce the total cooling water usage in the substrate treatment system 1 and the exposure apparatus 5.

Further, in this embodiment, the substrate treatment system 1 includes the gas supply apparatus 4 which supplies the atmosphere gas to the coating and developing treatment apparatus 2. The substrate treatment system 1 further includes the supply path 140 which connects the gas supply apparatus 4 and the exposure apparatus 5 and supplies the cooling water used in the gas supply apparatus 4 to the exposure apparatus 5. In other words, in this embodiment, by providing the above supply path 140, the cooling water supplied in the gas supply apparatus 4 is used also in the exposure apparatus 5. Therefore, according to this embodiment, it is possible to further reduce the total cooling water usage in the substrate treatment system 1 and the exposure apparatus 5.

In short, in this embodiment, the cooling water used in the coating and developing treatment apparatus 2 or the gas supply apparatus 4 is used again in the exposure apparatus 5 by taking advantage of the fact that the allowable temperature of the cooling water in the exposure apparatus 5 is higher than those in the coating and developing treatment apparatus 2 and the gas supply apparatus 4, so as to suppress the total cooling water usage.

Further, in this embodiment, the supply path 110 and the supply path 140 merge on the exposure apparatus 5 side, and the cooling water supply apparatus 3 mixes the cooling water used in the coating and developing treatment apparatus 2 and the cooling water used in the gas supply apparatus 4 and then supplies them to the exposure apparatus 5. Therefore, for example, in the case where the temperature of the cooling water used in the gas supply apparatus 4 is higher than the allowable temperature of the cooling water in the exposure apparatus 5 and the temperature of the cooling water used in the coating and developing treatment apparatus 2 is lower than the allowable temperature, the above mixture makes it possible to supply the cooling water whose temperature is lower than the allowable temperature to the exposure apparatus 5.

### Second Embodiment

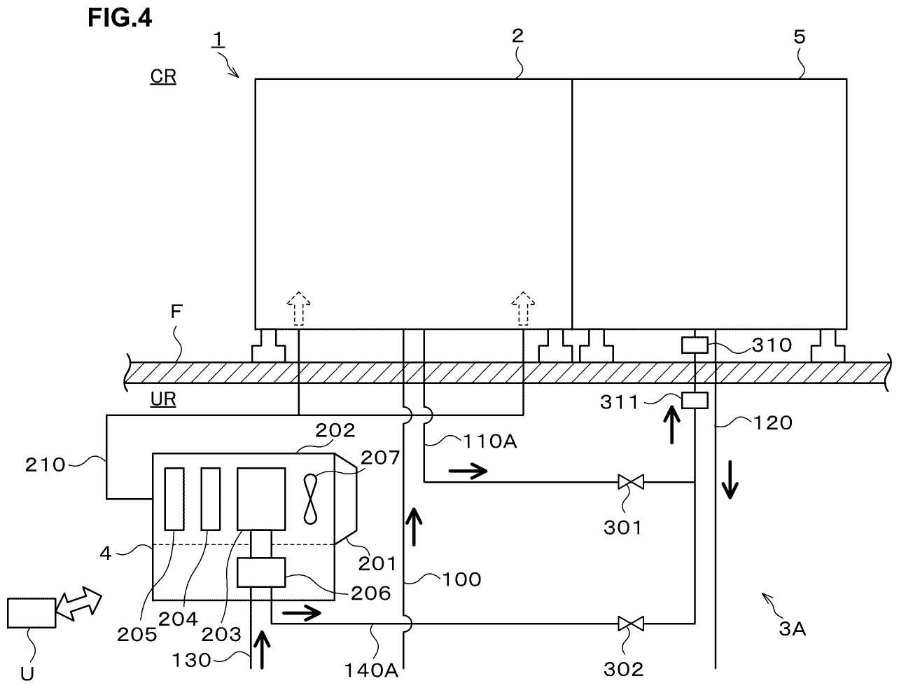

FIG. 4 is a view schematically illustrating a configuration of a substrate treatment system according to a second embodiment.

In a cooling water supply apparatus 3A according to this embodiment, a flow rate regulating valve 301 as a first flow rate regulator is provided in a supply path 110A connecting the coating and developing treatment apparatus 2 and the exposure apparatus 5 as illustrated. Further, a flow rate regulating valve 302 as a second flow rate regulator is provided in a supply path 140A connecting the gas supply apparatus 4 and the exposure apparatus 5. The flow rate regulating valve 301 is concretely provided on a side closer to the coating and developing treatment apparatus 2 than a merging portion of the supply path 110A with the supply path 140A. Besides, the flow rate regulating valve 302 is concretely provided on a side closer to the gas supply apparatus 4 than a merging portion of the supply path 140A with the supply path 110A.

Further, in this embodiment, a temperature sensor 310 is provided which measures the temperature of the cooling water to be supplied to the exposure apparatus 5. The temperature sensor 310 is concretely provided at the merging portion of the supply path 110A and the supply path 140A.

Further, in this embodiment, the control device U controls the flow rate regulating valves 301, 302 based on the measurement result by the temperature sensor 310 to regulate the mixture ratio of the cooling water to be supplied to the exposure apparatus 5 via the supply path 110A and the cooling water to be supplied to the exposure apparatus 5 via the supply path 140A. This can ensure that the temperature to be supplied from the cooling water supply apparatus 3A to the exposure apparatus 5 is appropriate. Specifically, in the case where the temperature of either the cooling water used in the coating and developing treatment apparatus 2 or the cooling water used in the gas supply apparatus 4 is higher than the allowable temperature of the cooling water in the exposure apparatus 5, the temperature to be supplied from the cooling water supply apparatus 3A to the exposure apparatus 5 can be made equal to or lower than the allowable temperature.

Further, in the case where the temperature sensor 310 is provided as in this embodiment, the control device U may notify the exposure apparatus 5 of the measurement result by the temperature sensor 310, namely, the information on the temperature of the cooling water to be supplied to the exposure apparatus 5. For example, the exposure apparatus 5 can determine whether it is possible to appropriately perform cooling in the exposure apparatus 5 by using the cooling water to be supplied to the exposure apparatus 5, based on the notified information on the temperature of the cooling water to be supplied to the exposure apparatus 5.

Note that the information about the cooling water to be supplied to the exposure apparatus 5 from the cooling water supply apparatus 3 (hereinafter, referred to as cooling water information) notified to the exposure apparatus 5 by the control device U is not limited to the information on the temperature. For example, a flow rate sensor 311 which measures the flow rate of the cooling water to be supplied to the exposure apparatus 5 is provided, and the control device U may notify the exposure apparatus 5 of the measurement result by the flow rate sensor 311 as the cooling water information. Note that the flow rate sensor 311 is concretely provided, for example, at the merging portion of the supply path 110A and the supply path 140A.

### Third Embodiment

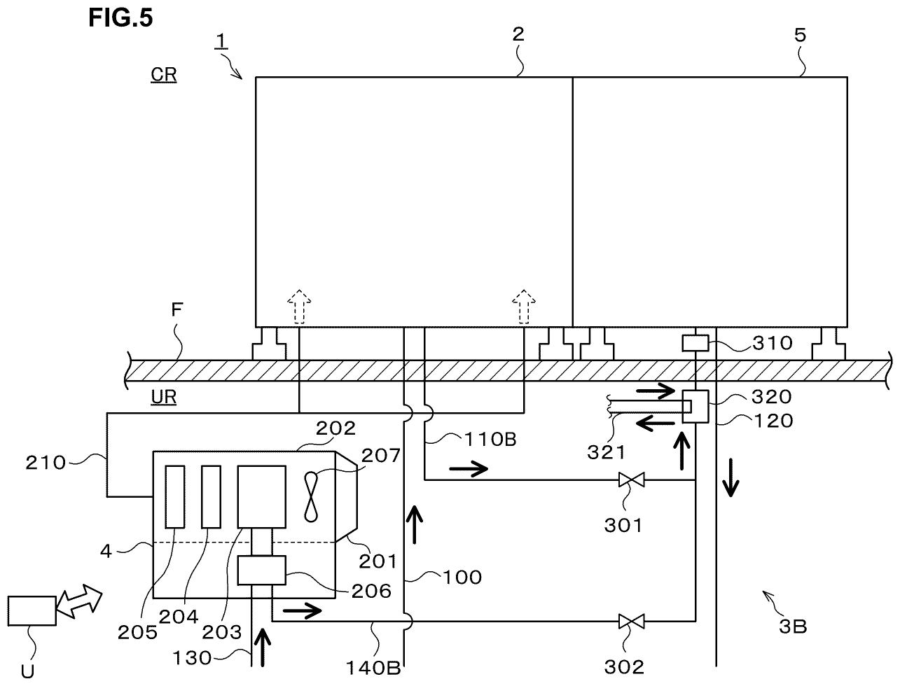

FIG. 5 is a view schematically illustrating a configuration of a substrate treatment system according to a third embodiment.

In a cooling water supply apparatus 3B according to this embodiment, a cooling unit 320 as a cooler which cools the cooling water to be supplied to the exposure apparatus 5. The cooling unit 320 cools the cooling water to be supplied to the exposure apparatus 5 by, for example, heat exchange with other cooling water. The cooling unit 320 has, for example, a circulation path 321 of the other cooling water, and the circulation path 321 is provided with a chiller unit (not illustrated) which cools the other cooling water increased in temperature due to the heat exchange.

Further, the cooling unit 320 is provided at a merging portion of a supply path 110B connecting the coating and developing treatment apparatus 2 and the exposure apparatus 5 and a supply path 140B connecting the gas supply apparatus 4 and the exposure apparatus 5 in the illustrated example.

By providing the cooling unit 320 as explained above, the temperature of the cooling water obtained by mixing the cooling water used in the coating and developing treatment apparatus 2 and the cooling water used in the gas supply apparatus 4 can be more surely made equal to or lower than the allowable temperature of the cooling water in the exposure apparatus 5.

Further, by providing the cooling unit 320 at the merging portion of the supply path 110B and the supply path 140B, it is possible to suppress an increase in total cooling water usage due to the provision of the cooling unit 320.

However, the arrangement position of the cooling unit 320 is not limited to the above example. For example, the cooling unit 320 may be provided on one or both of a side closer to the coating and developing treatment apparatus 2 than the merging portion of the supply path 110B and a side closer to the gas supply apparatus 4 than the merging portion of the supply path 140B.

### Fourth Embodiment

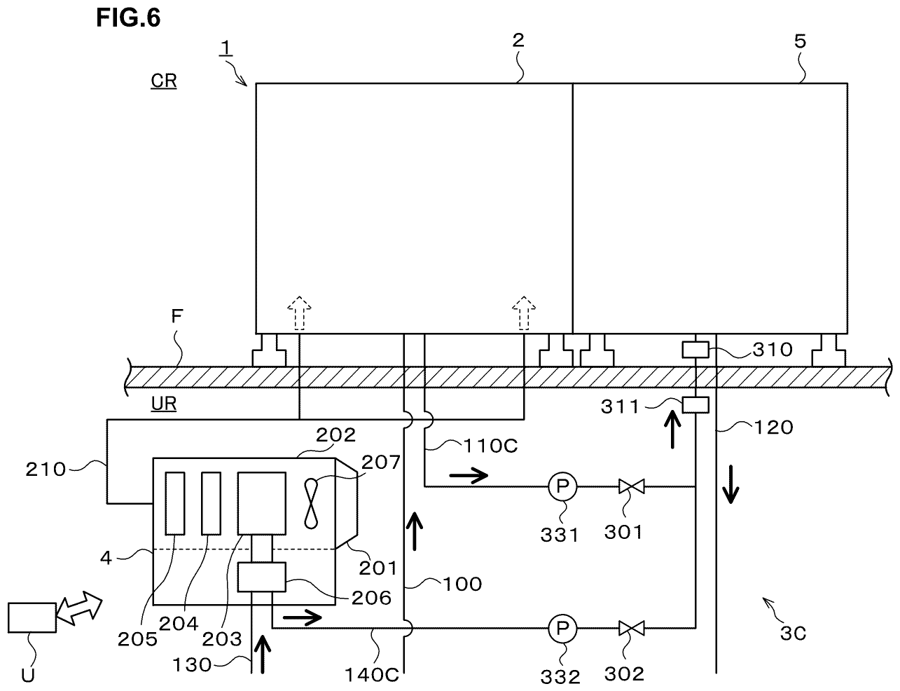

FIG. 6 is a view schematically illustrating a configuration of a substrate treatment system according to a fourth embodiment.

In a cooling water supply apparatus 3C according to this embodiment, a pump 331 which pressurizes the cooling water in a supply path 110C is provided in the supply path 110C connecting the coating and developing treatment apparatus 2 and the exposure apparatus 5 as illustrated. Further, a pump 332 which pressurizes the cooling water in a supply path 140C is provided in the supply path 140C connecting the gas supply apparatus 4 and the exposure apparatus 5. The pump 331 is concretely provided, for example, on a side closer to the coating and developing treatment apparatus 2 than a merging portion of the supply path 110C with the supply path 140C. Besides, the pump 332 is concretely provided on a side closer to the gas supply apparatus 4 than a merging portion of the supply path 140C with the supply path 110C.

With this configuration, even if the pressure loss in the cooling water flow path in the coating and developing treatment apparatus 2 or the pressure loss in the cooling water flow path in the gas supply apparatus 4 is large, the cooling water can be supplied at an appropriate pressure, namely, an appropriate flow rate from the cooling water supply apparatus 3C to the exposure apparatus 5.

### Modification Example of the Fourth Embodiment

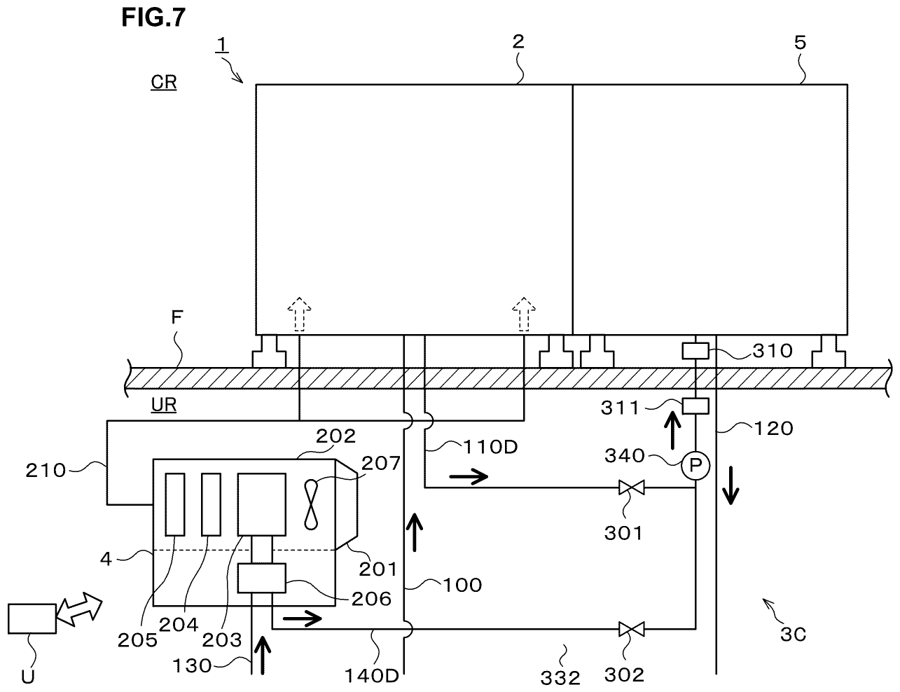

FIG. 7 is a view schematically illustrating a configuration of a substrate treatment system according to a modification example of the fourth embodiment.

In this example, a pump 340 made by integrating a pump which pressurizes the cooling water in a supply path 110D connecting the coating and developing treatment apparatus 2 and the exposure apparatus 5 and a pump which pressurizes the cooling water in a supply path 140D connecting the gas supply apparatus 4 and the exposure apparatus 5 is provided at a merging portion of the supply path 110D and the supply path 140D. In other words, the pump for the supply path 110D also serves as the pump for the supply path 140D. With this configuration, the cooling water can be supplied at an appropriate pressure, namely, an appropriate flow rate to the exposure apparatus 5 regardless of the pressure loss in the coating and developing treatment apparatus 2 or in the gas supply apparatus 4.

Further, according to this example, the number of pumps can be reduced, and therefore a reduction in cost can be achieved.

The embodiments disclosed herein are examples in all respects and should not be considered to be restrictive. Various omissions, substitutions and changes may be made in the embodiments without departing from the scope and spirit of the attached claims.

### EXPLANATION OF CODES

1 substrate treatment system
2 coating and developing treatment apparatus
5 exposure apparatus
110, 110A, 110B, 110C, 110D supply path
W wafer

1. A substrate treatment system connected to an exposure apparatus, the substrate treatment system comprising:
a substrate treatment apparatus configured to perform a treatment on a substrate; and
a first supply path connecting the substrate treatment apparatus and the exposure apparatus and configured to supply cooling water used in the substrate treatment apparatus to the exposure apparatus.

2. The substrate treatment system according to claim 1, further comprising:
a gas supply apparatus configured to supply atmosphere gas during a substrate treatment to the substrate treatment apparatus; and
a second supply path connecting the gas supply apparatus and the exposure apparatus and configured to supply cooling water used in the gas supply apparatus to the exposure apparatus.

3. The substrate treatment system according to claim 2, further comprising:
a first flow rate regulator configured to regulate a supply rate of the cooling water from the first supply path; and
a second flow rate regulator configured to regulate a supply rate of the cooling water from the second supply path.

4. The substrate treatment system according to claim 3, wherein
the first flow rate regulator and the second flow rate regulator regulate a mixture ratio of the cooling water from the first supply path and the cooling water from the second supply path.

5. The substrate treatment system according to claim 2, further comprising:
a first pump configured to pressurize the cooling water in the first supply path; and
a second pump configured to pressurize the cooling water in the second supply path.

6. The substrate treatment system according to claim 5, wherein
the first pump is provided at a merging portion of the first supply path and the second supply path and also serves as the second pump.

7. The substrate treatment system according to claim 1, further comprising
a cooler configured to cool cooling water to be supplied to the exposure apparatus.

8. The substrate treatment system according to claim 1, wherein
the substrate treatment system notifies the exposure apparatus of information about the cooling water to be supplied to the exposure apparatus.

9. A substrate treatment method using a substrate treatment system connected to an exposure apparatus, the substrate treatment method comprising
supplying cooling water used in a substrate treatment apparatus to the exposure apparatus.
